(19) United States
(12) Patent Application Publication
(10) Pub. No.: US 2002/0182853 A1
(43) Pub. Date: Dec. 5, 2002

(54) Method for removing hard-mask layer after metal-CMP in dual-damascene interconnect structure

(76) Inventors: Hsueh-Chung Chen, Yung-Ho City (TW); Teng-Chun Tsai, Hsin-Chu City (TW); Yung-Tsung Wei, Tainan (TW)

Correspondence Address: POWELL, GOLDSTEIN, FRAZER & MURPHY LLP, P.O. BOX 97223, WASHINGTON, DC, 20090-7223, US

(21) Appl. No.: 09/870,525

(22) Filed: May 31, 2001

(51) Int. Cl. H01L 21/4763

(52) U.S. Cl. 438/637

(57) ABSTRACT

The present invention provides a method for forming a dual-damascene interconnect structure and removing hard-mask layers thereon. First, a dielectric layer is formed on a substrate. Then, a first hard-mask layer and a second hard-mask layer are sequentially formed on the dielectric layer. An etching selectivity of the second hard-mask layer is different to an etching selectivity of the first hard-mask layer. Next, a first via hole is formed in the dielectric layer and exposes a portion of the substrate. Following, a second via hole is formed in the dielectric layer, wherein the second via hole is above and connects with the first via hole. Then, a conductive layer is formed on the substrate to fill the first via hole and the second via hole. Next, the conductive layer is planarized and stopped on the second hard-mask layer. Last, the second hard-mask layer is removed.

### BACKGROUND OF THE INVENTION

1. Field of the Invention

The present invention generally relates to a method for forming a dual-damascene interconnect structure, and more particularly relates to a method for removing a hard-mask layer after a metal-CMP process in a dual-damascene interconnect structure.

2. Description of the Prior Art

The use of chemical-mechanical polishing for removing excess copper in a damascene process and the use of damascene process for forming copper interconnects in the first place have evolved almost in a complementary fashion because of the nature of advances in the semiconductor technology. With the advent of very and ultra large scale integration (VLSI and ULSI) circuits, more devices are being packed into the same or smaller areas in a semiconductor substrate. At the same time, low resistance copper interconnects are being used more and more in order to improve further the performance of circuits. More devices in a given area on a substrate require better planarization techniques due to the unevenness of the topography formed by the features themselves, such as metal lines, or of the topography of the layers formed over the features. Because many layers of metals and insulators are formed successively one on top of another, each layer need to be planarized to a high degree if higher resolution lithographic processes are to be used to form smaller and higher number of features on a layer in a semiconductor substrate. Conventionally, etch-back techniques are used to planarize conductive (metal) or non-conductive (insulator) surfaces. However, some important metals, such as gold, silver and copper, which have many desirable characteristics as an interconnect, are not readily amenable to etching, and hence, the need for chemical-mechanical polishing (CMP).

As the shrinking in dimension of integrated circuits, Cu/low-k (k <3.0) integration scheme is the key point of reducing the RC delay and achieving the high performance interconnection. Usually, hard-mask layers are necessary for creating the complicated dual-damascene structure. The dual-damascene structure is formed with some hard dielectric materials as hard masks (such as silicon dioxide, silicon nitride, silicon carbide, and so on) having a thickness ranged from 100 to 2000 angstroms. After that, hard-mask layers are removed by CMP. However, it is very difficult to detect the endpoint in the very short time, typically within 30 seconds. Nevertheless, it is also very difficult to control the remaining hard-mask thickness in CMP process.

### SUMMARY OF THE INVENTION

An object of the invention is provided a method for forming a dual-damascene interconnect structure and removing hard-mask layers thereon.

Another object of the invention is provided a method for removing a hard-mask layer after a metal-CMP process in a dual-damascene interconnect structure.

In order to achieve previous objects of the invention, a method for forming a dual-damascene interconnect structure and removing hard-mask layers thereon is provided. The present method comprises following steps. First, a dielectric layer is formed on a substrate. Then, a first hard-mask layer and a second hard-mask layer are sequentially formed on the dielectric layer. An etching selectivity of the second hard-mask layer is different to an etching selectivity of the first hard-mask layer. Next, a first via hole is formed in the dielectric layer and exposes a portion of the substrate. Following, a second via hole is formed in the dielectric layer, wherein the second via hole is above and connects with the first via hole. Then, a conductive layer is formed on the substrate to fill the first via hole and the second via hole. Next, the conductive layer is planarized and stopped on the second hard-mask layer. Last, the second hard-mask layer is removed.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is the schematic representation of the structure after forming a dielectric layer, a first hard-mask layer, and a second hard-mask layer in a substrate, in accordance with the present invention;

FIG. 2 is the structure of FIG. 1 after forming a dual-damascene interconnect structure and filling a conductive material therein, in accordance with the present invention;

FIG. 3 is the structure of FIG. 2 after performing a chemical-mechanism polishing process, in accordance with the present invention;

FIG. 4 is the structure of FIG. 3 after removing the second hard-mask layer, in accordance with the present invention.

### DESCRIPTION OF THE PREFERRED EMBODIMENT

The semiconductor devices of the present invention are applicable to a broad rang of semiconductor devices and can be fabricated from a variety of semiconductor materials. The following description discusses several presently preferred embodiments of the semiconductor devices of the present invention as implemented in silicon substrates, since the majority of currently available semiconductor devices are fabricated in silicon substrates and the most commonly encountered applications of the present invention will involve silicon substrates. Nevertheless, the present invention may also be advantageously employed in gallium arsenide, germanium, and other semiconductor materials. Accordingly, application of the present invention is not intended to be limited to those devices fabricated in silicon semiconductor materials, but will include those devices fabricated in one or more of the available semiconductor materials.

In this invention, a set of new process steps was introduced to build the dual-damascene interconnect structure, and remove the hard-mask layers thereon. The method comprises following steps and will be detailed explained below, as shown in FIG. 1 to FIG.4.

Referring to FIG. 1, a substrate 10 is provided and then a dielectric layer 20 is formed on the substrate 10. The dielectric layer 20 is made of low-k materials and a dielectric constant of the dielectric layer 20 is lower than 3.0 or below. The dielectric layer 20 is formed by a chemical deposition method or a spin-on method which choose depending on the used low-k materials. Then, a first hard-mask layer 30 is deposited on the dielectric layer 20. The first hard-mask layer 30 is in a thickness between about 100 to 1000 angstroms and is made of dielectric, such as silicon nitride or silicon carbide. Next, a second hard-mask layer 32 is deposited on the first hard-mask layer 30. The second hard-mask layer 32 is in a thickness between about 500 to 2000 angstroms and is made of dielectric, such as oxide or silicon nitride. One of the most important things is that the second hard-mask layer 32 has different etching selectivity to the first hard-mask layer 30.

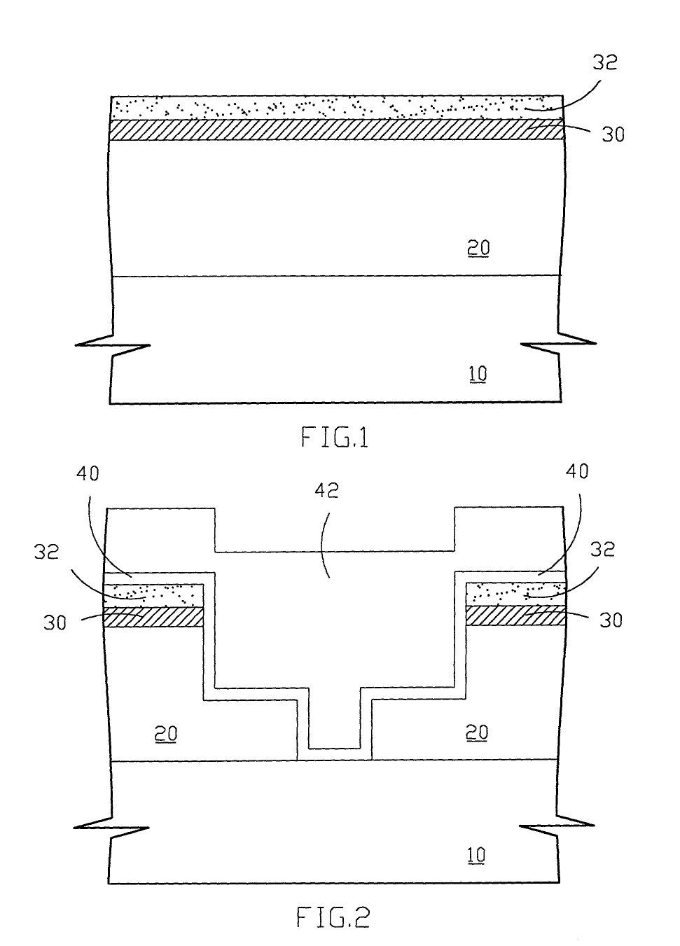

Referring to FIG. 2, after lithography processes, a dual-damascene interconnect structure is formed in the dielectric layer 20. The dual-damascene structure comprises a first via hole and a second via hole in the dielectric layer 20. The first via hole exposes a portion of the substrate 10, the second via hole is above and connects with the first via hole in the dielectric layer. The second via hole is used for a conductive line. Then, a metal liner layer is conformally formed on the second hard-mask layer and on a sidewall and a bottom surface of the first via hole and the second via hole. The metal liner layer 40 can be made of thallium nitride. Next, a conductive layer 42 is conformally deposited on the metal liner layer 40 to fill the dual-damascene structure. The conductive layer 42 is made of metal, such as copper.

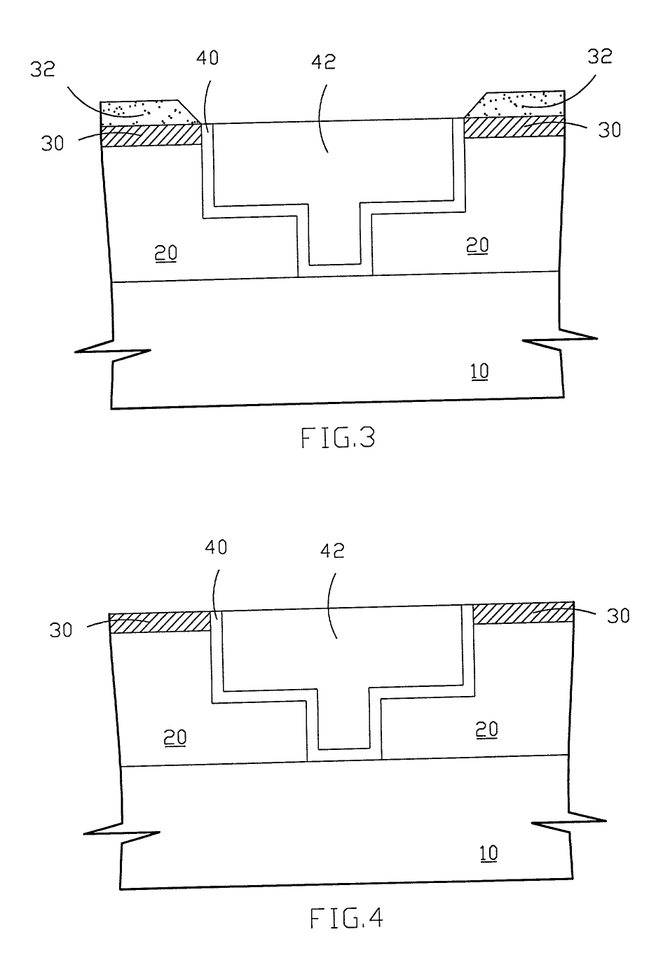

Referring to FIG. 3, a chemical mechanism polishing process is performed to remove the excess conductive layer 42 which is out of the dual-damascene structure. The chemical mechanism polishing process is stopped on the second hard-mask layer 32. Because the damage of the second hard-mask layer is allowed, the chemical mechanism polishing process is easy to control.

Referring to FIG. 4, following, the second hard-mask layer 32 is removed. Because the second hard-mask layer 32 has different etching selectivity to the first hard-mask layer 30, the second hard-mask layer 32 can easily removed by using a wet or dry etching process. Furthermore, in the etching step of removing the second hard-mask layer 32, the first hard-mask layer 30 can effectively protect the dielectric layer 20.

In this invention, after forming a dielectric layer on a substrate, a first hard-mask layer was capped. Then, a second hard-mask layer having different etching selectivity was deposited. After lithography processes, a dual-damascene structure is formed and then depositing liner and copper. Following, a Cu-CMP process is implemented to remove the overburden copper above the hard-mask surface and stopped on the second hard-mask layer. Finally, the second hard-mask layer was removed by wet/dry etching and then a flat surface is left. The first hard-mask layer did not remove in the etching step, so as to act as a protection layer of the dielectric layer underneath.

To sum up the foregoing, the method is using a first and second dielectric hard-masks to form a dual-damascene structure. The second hard-mask dielectric is having different etching selectivity from the first one. The Cu-CMP process is stopped on the second hard-mask dielectric and the second hard-mask dielectric is removed by using wet or dry etching process.

Of course, it is to be understood that the invention need not be limited to these disclosed embodiments. Various modification and similar changes are still possible within the spirit of this invention. In this way, the scope of this invention should be defined by the appended claims.

What is claimed is:

1. A method for forming a dual-damascene interconnect structure and removing hard-mask layers thereon, said method comprising:
providing a dielectric layer on a substrate;
sequentially forming a first hard-mask layer and a second hard-mask layer on said dielectric layer, wherein an etching selectivity of said second hard-mask layer is different to an etching selectivity of said first hard-mask layer;
forming a first via hole in said dielectric layer to expose a portion of said substrate;
forming a second via hole in said dielectric layer, wherein said second via hole is above and connects with said first via hole;
forming a conductive layer on said substrate to fill said first via hole and said second via hole;
planarizing said conductive layer and stopping on said second hard-mask layer; and
removing said second hard-mask layer.

2. The method according to claim 1, wherein a dielectric constant of said dielectric layer is lower than 3.0.

3. The method according to claim 1, wherein said dielectric layer is formed by a chemical vapor deposition method.

4. The method according to claim 1, wherein said dielectric layer is formed by a spin-on method.

5. The method according to claim 1, wherein said first hard-mask layer is in a thickness between about 100 and 1000 angstroms.

6. The method according to claim 1, wherein said first hard-mask layer is selected from the group consisting of oxide and silicon nitride.

7. The method according to claim 1, wherein said second hard-mask layer is in a thickness between about 500 and 2000 angstroms.

8. The method according to claim 1, wherein said second hard-mask layer is selected from the group consisting of silicon nitride and silicon carbide.

9. The method according to claim 1, further comprising a step of forming a metal liner layer on a sidewall and a bottom surface of said first via hole and said second via hole before depositing said conductive layer.

10. The method according to claim 1, wherein said conductive layer is made of copper.

11. The method according to claim 1, wherein planarizing said conductive layer is using a chemical-mechanism polishing process.

12. The method according to claim 1, wherein removing said second hard-mask layer is using an etching process.

13. A method for forming a dual-damascene interconnect structure and removing hard-mask layers thereon, said method comprising:
providing a dielectric layer on a substrate, wherein a dielectric constant of said dielectric layer is lower than 3.0;
sequentially forming a first hard-mask layer and a second hard-mask layer on said dielectric layer, wherein an etching selectivity of said second hard-mask layer is different to an etching selectivity of said first hard-mask layer;
forming a second via hole in said dielectric layer, wherein said second via hole is above and connects with said first via hole;
forming a conductive layer on said substrate to fill said first via hole and said second via hole;
forming a metal liner layer on a sidewall and a bottom surface of said first via hole and said second via hole;
forming a conductive layer on said substrate to fill said first via hole and said second via hole, wherein said conductive layer is made of copper;;
performing a chemical-mechanism polishing process to remove said conductive layer and to stop on said second hard-mask layer; and
removing said second hard-mask layer by using an etching process.

14. The method according to claim 13, wherein said dielectric layer is formed by a chemical vapor deposition method.

15. The method according to claim 13, wherein said dielectric layer is formed by a spin-on method.

16. The method according to claim 13, wherein said first hard-mask layer is in a thickness between about 100 and 1000 angstroms.

17. The method according to claim 13, wherein said first hard-mask layer is selected from the group consisting of oxide and silicon nitride.

18. The method according to claim 13, wherein said second hard-mask layer is in a thickness between about 500 and 2000 angstroms.

19. The method according to claim 13, wherein said second hard-mask layer is selected from the group consisting of silicon nitride and silicon carbide.

20. The method according to claim 13, wherein said etching process is selected from the group consisting of a dry-etching process and a wet-etching process.
